(19) United States
(12) Patent Application Publication
(10) Pub. No.: US 2010/0200995 A1
(43) Pub. Date: Aug. 12, 2010

(54) COUPLING LAYER COMPOSITION FOR A SEMICONDUCTOR DEVICE, SEMICONDUCTOR DEVICE, METHOD OF FORMING THE COUPLING LAYER, AND APPARATUS FOR THE MANUFACTURE OF A SEMICONDUCTOR DEVICE

(75) Inventors: Philippe Monnoyer, Grenoble (FR); Maria Luisa Calvo-Munoz, Grenoble (FR); Janos Farkas, Austin, TX (US); Sabine Szunerits, Grenoble (FR)

Correspondence Address: LARSON NEWMAN & ABEL, LLP, 5914 WEST COURTYARD DRIVE, SUITE 200, AUSTIN, TX, 78730, US

(73) Assignee: Freeescale Semiconductor, Inc, Austin, TX (US)

(21) Appl. No.: 12/665,070

(22) PCT Filed: Jul. 9, 2007
(86) PCT No.: PCT/IB07/53437

§ 371 Date: Dec. 17, 2009

(51) Int. Cl. H01L 23/535; B05C 13/00; B05D 3/06

(52) U.S. Cl. 257/773; 118/500; 427/553; 257/E23.168

(57) ABSTRACT

Molecules of a coupling layer composition in a semiconductor device are bidimensionally polymerized in order to provide enhanced moisture blocking effect, particularly when the coupling layer is formed on a porous layer, such as a porous dielectric layer. The deposition of the coupling layer on the underlying structure and/or the cross-polymerization of the coupling layer composition and/or a final metallization can be photo-activated, especially, but not only, using an ultraviolet light.

### FIELD OF THE INVENTION

The present invention generally relates to a semiconductor device including a coupling layer, the composition of the coupling layer, and a method and apparatus for the manufacture of such a semiconductor device, including photoactivation of the coupling layer composition.

### BACKGROUND OF THE INVENTION

The use of interconnects having a reduced dielectric constant (k) in integrated circuits is generally known in order to reduce resistance-capacitance delay. An example of a conventional approach in this regard is the use of porous carbonated silicon dioxide films.

The term “carbonated silicon dioxide films” and the corresponding formula “SiOC” are used to designate silicon dioxide films including carbon therein (e.g., by using CH₃SiH₃ in place of the SiH₄ that is often used as a precursor in CVD deposition of a silicon dioxide layer). Such films are sometimes also referred to in the art as carbon-doped silicon dioxide films. Examples of carbon-doped silicon dioxide films are commercially available from companies such as Applied Materials, Novellus Systems, Trikon, Dow Chemicals, Rohm & Haas, and JSR.

However, it is known in the art that a silicon oxide-containing material (like a carbonated silicon dioxide) has a substantial population of surface hydroxyl groups (also referred to herein as silanol) on its surface. These groups have a strong tendency to take up water because they are highly polarized. They are generated by the break up of siloxane (Si—O—Si) bridges at the surface of the material. These siloxane structures at the material surface have an uncompensated electric potential and so can be considered to be “strained”. They react readily with ambient moisture to form the surface hydroxyl groups. If the silicon oxide-containing material is porous, the surface hydroxyls and the adsorbed water molecules may have a tendency to propagate into the bulk of the material. This causes an increase in the dielectric constant and reduces film reliability.

For example, when a carbonated silicon oxide is dry-etched, the oxidizing plasma reduces the carbon content at the surface of the material and therefore increases the population of surface hydroxyls. The dielectric constant k thus increases after dry etching, so the k value of the film must be “restored.” A conventional example of restoring the dielectric constant is applying a supercritical CO₂ treatment with hexamethyldisilazane (HMDS).

A similar effect occurs in other materials, such as metal oxides, present on the surface of a wafer. In that case, metal ion-oxide bonds located at the surface of the material have an uncompensated electric potential. This likewise leads to a ready reaction with ambient moisture so as to form surface hydroxyl groups. Once again, if the material is porous, the surface hydroxyls and adsorbed water molecules tend to propagate into the bulk of the material and lead to an unwanted increase in dielectric constant.

In addition to problems caused by moisture present in ambient air, it is also conventional to use aqueous cleaning solutions to clean the surface of the wafer during semiconductor fabrication. For example, when a semiconductor integrated circuit is manufactured, vias and other trench-like structures must be etched in one or more layers formed on a semiconductor substrate. During etching, polymer residues generated by a reaction between hydrocarbon etchant gases in the plasma and the substrate material may build up. In addition, metallic species (e.g., copper) may be inadvertently sputtered onto the sidewalls.

Therefore, in order to clean surfaces of the semiconductor structure when necessary, the use of aqueous cleaning solutions such as dilute hydrofluoric acid (HF) or an organic acid/base solution is known.

However, if the structure tends to absorb water (especially if it is porous), aqueous cleaning solutions may not be suitable. In particular, a porous material may adsorb water from the cleaning fluids for the reasons indicated above. This problem may be even more pronounced if the dielectric layer is damaged by plasma etching during a prior etching process.

Besides increasing the dielectric constant of a porous dielectric layer, adsorbed water can also cause problems during subsequent manufacture of the circuit, particularly degassing and reliability problems.

For the reasons described above, it is important to prevent water adsorption and uptake if porous dielectric materials are used to form interconnects. Moisture uptake in a porous dielectric could also possibly corrode metallic barrier layers subsequently formed thereon.

Some known approaches to combat moisture uptake by porous dielectric materials during manufacture and use of a semiconductor integrated circuit include “dielectric restoration” as referred to hereinabove, as well as “pore sealing.”

Pore sealing blocks access to the pores in the porous material, for example, by modifying the surface of the porous material (e.g. using an organosilane treatment). Alternatively, a second thin dielectric film may be deposited on the surface of the porous dielectric layer. More particularly, the thin dielectric film can be applied to the porous dielectric layer after vias have been etched therein. However, this second dielectric actually raises the effective dielectric constant, and therefore reduces the underlying advantage of using a porous underlying dielectric.

In addition to the foregoing issues concerning porous dielectric materials, subsequent conventional metallization (i.e., the formation of various metal layer structures, including barrier layers) is relatively slow and complex, and is therefore relatively expensive. In this regard, atomic layer deposition, chemical vapor deposition, and physical vapor deposition are typical methods for forming metal layers. Such processes require, in particular, separate and relatively complex process equipment operating under strict operating conditions. This also undesirably increases the overall footprint of equipment necessary for fabrication. In addition, the effectiveness of metal layer deposition depends on the nature of the underlying surface. In some cases, metallization can be significantly retarded by an unfavorable underlying surface.

In addition, conventional gas and/or vapor phase process equipment is usually application specific. That is, a CVD reaction chamber, for example, can generally only be used for CVD processing. This means that a semiconductor device fabrication line requires a relatively large number of difference pieces of separate process equipment. An issue related to using separate pieces of equipment is that transporting semiconductor substrates between them is a delicate process that may expose substrates to external contamination and the like.

U.S. Pat. No. 6,110,011, U.S. Pat. No. 6,143,126, U.S. Pat. No. 6,294,059, and U.S. Pat. No. 6,352,467 disclose general examples of integrated semiconductor substrate processing systems, but none are believed to emphasize the above-noted drawbacks of gas/vapor phase processing or useful alternatives thereto, especially with respect to metal deposition.

Yu et al. (Journal of the Electrochemical Society, 150 (8) F156-F163 (2003)) modify the surface of a low K material (namely, SiLK from Dow Chemical) with an argon plasma to create peroxide and hydroperoxide surface species. The latter species do react upon UV irradiation with 4-vinylbenzyl chloride to give a polyvinyl benzyl chloride growth on the surface. Afterwards viologen groups are grafted on the benzyl chloride free groups. The resulting groups complex palladium or gold ions from a solution. Afterwards a UV irradiation gives a metallic photoreduction and electroless deposition of copper follows.

Dicks et al. describe depositing platinum from a platinum-containing organometallic subjected to UV irradiation. IEEE Transactions on Semiconductor Manufacturing, Vol. 17, No. 2, MAY 2004.

Patent Application No. PCT/EP2005/001510 (filed Feb. 15, 2005) describes a technique for cleaning via and trench structures after an etching step, using liquid cleaning agents.

Patent Application No. PCT/EP2005/010688 (filed Sep. 1, 2005) describes a polymeric composition for passivating a porous, low dielectric constant dielectric layer while simultaneously providing reaction sites promoting the electroless metal layer deposition thereon.

### SUMMARY OF THE INVENTION

Accordingly, the present invention relates to a polymeric coupling material acting on the one hand to promote or facilitate metallization (such as liquid phase barrier deposition) and on the other hand comprising molecules which are cross-polymerized between themselves in order to provide a bidimensional polymerization structure having a desirably increased pore sealing function, a semiconductor device including a layer of such a material, a method of manufacturing such a semiconductor device including one or more photoactivation steps (especially but not only for inducing cross-polymerization), and an apparatus for manufacturing such a semiconductor device, as set forth in the claims appended hereto.

### BRIEF DESCRIPTION OF THE DRAWINGS

The presently described and claimed invention will be even more clearly understandable with respect to the appended drawings, in which:

FIG. 1 schematically illustrates a sequence of steps performed in an apparatus for manufacturing a semiconductor device according to an embodiment of the present invention, given strictly by way of invention;

FIG. 2 is a fragmentary schematic cross-sectional view of a portion of a semiconductor device structure fabricated in accordance with an embodiment of the present invention;

FIG. 3 illustrates a reaction between an embodiment of the present invention, given by way of example, with a hydroxyl group on a silica surface;

FIG. 4 illustrates photoreaction of a photoactivator according to part of an embodiment of the present invention, given by way of example, as well as a further crosslinking reaction between molecules of a coupling material, according to an embodiment of the present invention given by way of example; and

FIG. 5 is a schematic partial perspective view of a part of a semiconductor device having a cross-linked coupling material deposited thereon, according to an embodiment of the invention, given by way of example.

### DETAILED DESCRIPTION OF PREFERRED EMBODIMENTS

Some preferred embodiments of the present invention are described hereinbelow.

The mention of a “semiconductor substrate” herein includes and encompasses, without limitation, semiconductor wafers, partially cut groups of semiconductor dice, and individual semiconductor chips.

The mention of structures or layers or the like formed “on” a semiconductor substrate may include the presence of the structure or layer or the like directly or indirectly on the surface of the semiconductor substrate.

In description of the present invention set forth herein, the term “coupling layer” may be equated with “passivating coupling layer” in terms of passivating and coupling functions of the referenced material. For convenience and brevity herein, however, reference is made to a “coupling layer” or “coupling material” etc., particularly as it may be used for its metallization promoting characteristic without necessarily providing a passivating function.

A coupling material according to the present invention may for example be deposited in a multi-step surface functionalization process. For simplicity of description, a two step process is described, but longer molecules can be of course formed by repeating the steps generally described hereinbelow. A coupling material according to the present invention provides both pore sealing functionality for sealing a porous underlying layer (such as a dielectric) as well as a coupling function for promoting or facilitating a subsequently formed metal layer.

For example, the porous dielectric surface is reacted with a first silane component in a silanization step, such that at least one of the functional groups presented by the first silane component reacts with the surface hydroxyls on the porous dielectric surface. In doing so, the first silane component seals the porosity of the underlying layer while leaving at least one hydrolizable functional group on the surface. Preferably, the reaction is carried out in a controlled atmosphere, like nitrogen or argon, to increase the range of usable silanes. In the absence of moisture and oxygen, an aggressive sylilating agent (e.g., trifluorosulfonates, aminosilanes, etc.) can be applied.

Reacting the first silane component with the underlying surface may be promoted or enhanced by a photoactivation step concurrent with or after silanization. The photoactivation step is wavelength and temperature dependent, and may be carried out at, for example, wavelengths of 190 nm to 10 μm, a temperature of about 0° C. to about 400° C., for about 1 to 1000 seconds. In an even more preferred example, photoactivation can be carried out at a wavelength of between about 190 nm to about 500 nm, for about 1 to 60 seconds, at a temperature between about 10° C. and 100° C.

After dehydrating the surface and sealing the porosity thereof, as above, a conventional aqueous via-cleaning step can be performed. In this step, at least one functional group at the other “end” of the first silane polymeric component is hydrolyzed so as to present one or more silanol groups. These silanol groups are the sites at which respective functional groups of a second silane component react so as to couple electron donor ligands to the silanol groups. The ligands are nucleating sites for subsequent liquid phase metal barrier deposition.

An appropriate first polymeric component for the first step is, for example, an organosilane according to the following general formula:

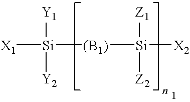

in which:
n₁ is an integer greater than or equal to 1,
each Si is a silicon atom;
X₁ is a functional group able to react with a surface hydroxyl site of the dielectric material and bind to its surface,
Y₁ is either:
   X₃, which is a further functional group able to react with a surface hydroxyl site of the dielectric material and bind to its surface,
   H, which is a hydrogen atom, or
   R₁, which is an organic group;
Y₂ is either:
   X₄, which is a further functional group able to react with a surface hydroxyl site of the dielectric material and bind to its surface,
   H, which is a hydrogen atom, or
   R₂, which is an organic group,
B₁, the presence of which is optional, is a bridging group,
Z₁ is either:
   R₃, which is an organic group,
   H, which is a hydrogen atom, or
   X₅, which is a hydrolizable functional group, and
Z₂ is either:
   R₄, which is an organic group,
   H, which is a hydrogen atom, or
   X₆, which is a hydrolizable functional group; and
X₂ is a hydrolizable functional group.

Some examples of first organosilane components according to the description include:

### Example 1

### (Strong Amino (Basic) Group for Dehydrating, and Weak Methoxy Group for Rehydrating Methanol Bi-Product (Inert to Surface))

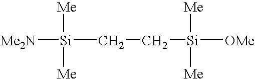

### Example 2

### Increase the Efficiency of Steric Shielding by Additional Organic Groups

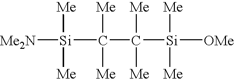

### Example 3

### Silicon Backbone to Increase Thermal Stability

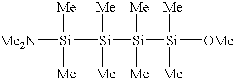

### Example 4

### Aromatic Bridging Group to Increase Thermal Stability

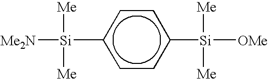

### Example 5

### Strong Hydrolyzable Amino Groups on both Ends—Amine (Basic) Product; Aromatic Bridging Group

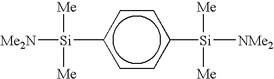

### Example 6

### Strong Fluoromethanesulfonate Hydrolyzable Groups on both Ends—Trifluorometanesulfanete (Acid) Product

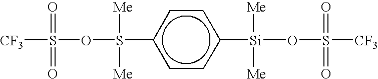

An appropriate polymeric component for the second step is an organosilane according to the general formula:

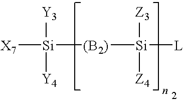

in which:
n₂ is an integer equal to or greater than or equal to 0,
each Si is a silicon atom;
X₇ is a functional group able to react with a hydrolyzed functional group of the first organosilane molecule,
Y₃ is either:
   X₈, which is a further functional group able to react with a hydrolyzed functional group of the first organosilane molecule,
   H, which is a hydrogen atom, or
   R₅, which is an organic group;
Y₄ is either:
   X₉, which is a further functional group able to react with a hydrolyzed functional group of the first organosilane molecule,
   H, which is a hydrogen atom, or
   R₆, which is an organic group,
B₂, the presence of which is optional, is a bridging group,
Z₃ is either:
   R₇, which is an organic group,
   H, which is a hydrogen atom, or
   L₁, which is a ligand having an electron donor functionality and which is able to act as a metal nucleation site,
Z₄ is either:
   R₈, which is an organic group,
   H, which is a hydrogen atom, or
   L₂, which is a ligand having an electron donor functionality and which is able to act as a metal nucleation site, and
L is a ligand having an electron donor functionality and is able to act as a metal nucleation site.

Some examples of second (or at least subsequent) organosilanes according to the description include:

### Example 1

### Strong Amino (Basic) Group for Coupling, and a Vinyl Ligand for Nucleation

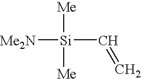

### Example 2

### Alternative Acidic Fluoromethanesulfonate Coupling Group

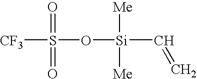

### Example 3

### Alternative Acetylenyl Ligand

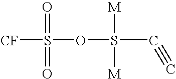

Taking, for example, a reaction between Example 1 of the first organosilanes and Example 1 of the second organosilanes, the surface will be terminated by Si (Me2)-OH. The OH will react with NMe2 of the second organosilane to form a Si—O—Si bond therebetween and an HNMe2 by-product.

The organic group(s) R may be polar or apolar. Apolar organic group(s) R may be, for example, an optionally halogenated C₁ to C₁₀ alkyl, C₂ to C₁₀ alkenyl, or O₆ to C₁₀ aryl or aralkyl group, which is/are preferably selected from: methyl, ethyl, propyl, butyl, phenyl, pentafluorophenyl, 1,1,2-trimethylpropyl (thexyl), and allyl. Polar organic groups R could be, for example, primary and secondary amines or alkoxy groups, and could be, for example and without limitation, methyl methacrylate. Strictly for simplicity and brevity, examples of the present invention described herein may not refer to both apolar and polar organic groups R systematically, but contemplation of both by the present invention should be understood.

Functional groups X should have a structure such that they are able to react with respective surface hydroxyl sites of the porous dielectric material so as to attach one of more shielding layers in the passivating coupling material to the surface of the porous dielectric material. More particularly, the functional groups X react by the elimination of the surface hydroxyl. Some examples of appropriate functional groups X in this regard include, without limitation, -chloride, -bromide, iodide, acryloxy-, alkoxy-, acetamido, acetyl-, allyl-, amino-, cyano-, epoxy-, imidazolyl, mercapto-, methanosulfonato-, sulfonato-, trifluoroacetamido, and urea-containing groups

The one or more ligands L should have an electron donor functionality, and, once the molecule is attached to the surface of the porous dielectric material, forms a reaction site for metal nucleation during a subsequent liquid phase metallization process. Ligands appropriate to the present invention include, without limitation, vinyl, allyl, 2-butynyl, cyano, cyclooctadienyl, cyclopentadienyl, phosphinyl, alkylphosphinyl, sulfonato, amine groups, carboxylic acids, carboxylates, and thiols.

In certain instances, the functional groups X and the ligands L could be the same mono-, bi-, and tri-functional amines (which would form strong interactions with both the porous dielectric thereunder and the metal layers subsequently formed thereon).

In addition, the one or more ligands presented have an electron donor functionality and provide nucleation sites for the subsequently deposited metal. The fact that some functional groups Z can be additional ligands (i.e., in addition to L) further enhances the formation of a metal layer by presenting additional nucleation sites.

The bridging group B, if present, can be, for example, a divalent bridging group (such as oxygen or sulfur), a trivalent bridging group (such as nitrogen or phosphorus), or a tetravalent bridging group (such as carbon or silicon), and may be, more particularly, silylene and unsaturated aromatic carbon-containing groups such as m-phenylene, p-phenylene, and p,p′-diphenyl ether. The bridging group, when present, may further improve the thermal stability of the passivating coupling material molecule.

A feature of the present invention relates to the fact that at least some of the organic groups R (of the first and/or second organosilane components) are able to react with another organic group R of another one of the first and/or second organosilane components in order to be cross-linked. In other words, the present invention contemplates a transverse polymerization in addition to the polymerization between the two or more organosilane components. This bidimensional polymerization provides, among other effects, an increased sealing effect against moisture intake because the transverse polymerization between molecules of the coupling composition even better blocks moisture uptake.

In particular, this cross-linking between respective molecules of the coupling composition can desirably be photoactivated as a function of light wavelength, temperature, and exposure time. The photoactivation step may be carried out at, for example, wavelengths of 190 nm to 10 μm, a temperature of about 0° C. to about 400° C., for about 1 to 1000 seconds. In an even more preferred example, photoactivation can be carried out at a wavelength of between about 190 nm to about 500 nm, for about 1 to 60 seconds, at a temperature between about 10° C. and 100° C.

The present invention is not restricted to using a plurality of organosilane components as above. For example, a pore sealing approach using a material similar to that disclosed in PCT/EP2005/010688 can also be used, in which the reaction of various molecules with the underlying dielectric (i.e., silanization) and the cross-polymerization between respective organic groups R of respective molecules of the composition can be photo-induced using parameters comparable to those set forth above.

A variety of coupling materials can be used to according to the present invention. Generally, an appropriate coupling material according to the present invention:
includes at least one functional group that can react with surface hydroxyls commonly present on the surface of the porous dielectric material,
includes at least one second functional group (i.e., a ligand) having an electron donor functionality to provide a reactive site (more specifically, a metal nucleation site) that facilitates or promotes subsequent metallization,
preferably, but not necessarily, includes at least two silicon atoms in the molecular backbone for thermally stabilizing the passivating coupling material, especially during subsequent relatively high temperature processing steps, and
preferably includes a plurality of organic shielding groups, which form at least one, and preferably at least two, shielding layers above the surface of the porous dielectric layer for blocking moisture uptake, at least some of organic shielding groups of a given molecule of the coupling material being able to react with respective organic shielding groups of another molecule of the coupling material in order to cross-link the molecules of the coupling material.

An example of an appropriate coupling material is an organosilane according to the following general formula:

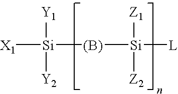

in which:

n is an integer equal to or greater than 1 (i.e., 1, 2, 3, 4, 5, 6, 7 . . . ),

each Si is a silicon atom;

X₁ is a functional group able to react with a surface hydroxyl site of the porous dielectric material.

Y₁ is either:
X₂, which is a further functional group able to react with a surface hydroxyl site of the porous dielectric material,
H, which is a hydrogen atom, or
R₁, which is an organic group;

Y₂ is either:
X₃, which is a further functional group able to react with a surface hydroxyl site of the porous dielectric material,
H, which is a hydrogen atom, or
R₂, which is an organic group

B, the presence of which is optional, is a bridging group,

Z₁ is either:
R₃, which is an organic group,
H, which is a hydrogen atom, or
L₁, which is a further ligand having an electron donor functionality and is able to act as a metal nucleation site,

Z₂ is either:
R₄, which is an organic group,
H, which is a hydrogen atom, or
L₂, which is a further ligand having an electron donor functionality and is able to act as a metal nucleation site, and

L is a ligand having an electron donor functionality and is able to act as a metal nucleation site.

The strength of the bond between the passivating coupling material and the porous dielectric material, and the speed at which it reacts with the surface hydroxyls is believed to depend on what functional groups are present and on the number of the silicon groups in the passivating coupling material.

The presence of at least one, and preferably at least two, silicon atoms in the main chain (“backbone”) of the molecule as described herein makes the molecule more thermally stable, particularly in view of the temperatures encountered in performing subsequent process steps. For example, after liquid phase metallization, a subsequent dielectric layer deposition and cure may entail temperatures of, for example, about 350° C. In comparison, for example, a molecule having carbon (for example, aliphatic or aromatic carbon) in the backbone would likely oxidize at such temperatures.

In general, the various non-limitative examples of the bridging groups B, the functional groups X, the organic groups R, and the ligands L as described above with respect to the coupling composition comprising a plurality of organosilane “components” are equally applicable to the silane components that constitute the composition.

With porous materials it could be expected that the size of the shielding groups R should be proportional to the size of pores. Prior research suggests that an organic layer less than about 25 Angstroms thick can be efficient for sterically shielding a surface from water penetration, even at elevated temperatures.

In the present invention, the length of the hydrocarbon chain can be easily adjusted to optimize the efficiency of steric shielding to the pore size of the dielectric.

The concept of the molecule will be shown using a series of representative compounds by way of example and without limitation. It will be appreciated that the example molecules shown below can be made longer or shorter according to the number of n monomers that are present therein. The index n is most generally an integer of 1 or greater. More preferably, n is an integer between 1 and 30, inclusive. Most preferably, n is an integer between 1 and 18, inclusive, i.e., 1, 2, 3, 4, 5, 6 . . . 17, or 18.

### Example 1

### Methoxy-tetramethyl-vinyl-disilane

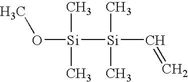

in which the X₁ functional group is H₃CO— (methoxy) group; the Y₁, Y₂, Z₁, Z₂ functional groups are —CH₃ (methyl) organic shielding groups; B is absent; and the ligand L is a —CH═CH₂ vinyl group.

### Example 2

### Trimethoxy-dimethyl-vinyl-disilane

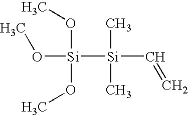

in which the X₁, Y₁, and Y₂ functional groups are H₃CO— (methoxy groups); the Z₁ and Z₂ functional groups are CH₃ methyl organic shielding groups; B is absent; and the ligand L is a —CH═CH2 vinyl group.

### Example 3

### Vinyltetramethylmethoxydisiloxane

### Bridging Group B Present

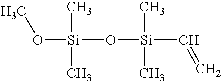

in which the X₁ functional group is a H₃CO— (methoxy) group; the Y₁, Y₂, Z₁, Z₂ functional groups are —CH₃ (methyl) organic shielding groups; the bridging group B is oxygen (forming a disiloxane compound); and the ligand L is a C═CH₂ vinyl group.

The addition of a bridging group B (such as oxygen in this example) can significantly affect the thermal stability of the coupling layer. Silylene and unsaturated carbon-containing carbene groups such as m-phenylene, p-phenylene, and p,p′-diphenyl ether are additional examples of bridging groups that can be used according to this invention to further improve the thermal stability of the passivating coupling material molecule.

### Example 4

### Methoxy-tetramethyl-butyl-disilane

### Alternative Ligand

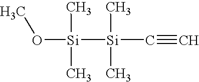

in which the X₁ functional group is a H₃CO— (methoxy) group; the Y₁, Y₂, Z₁, Z₂ functional groups are —CH₃ (methyl) organic shielding groups; the bridging group B is absent; and the ligand L is a —C≡CH acetylenyl group.

### Example 5

### Methoxy-hexamethyl-vinyl-trisilane

### Alternative Molecule Length

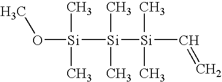

in which the X₁ functional group is a H₃CO— (methoxy) group; Y₁, Y₂, Z₁, Z₂ functional groups are —CH₃ (methyl) organic shielding groups; the bridging group B is absent; and the ligand L is a —CH═CH₂ (vinyl) group.

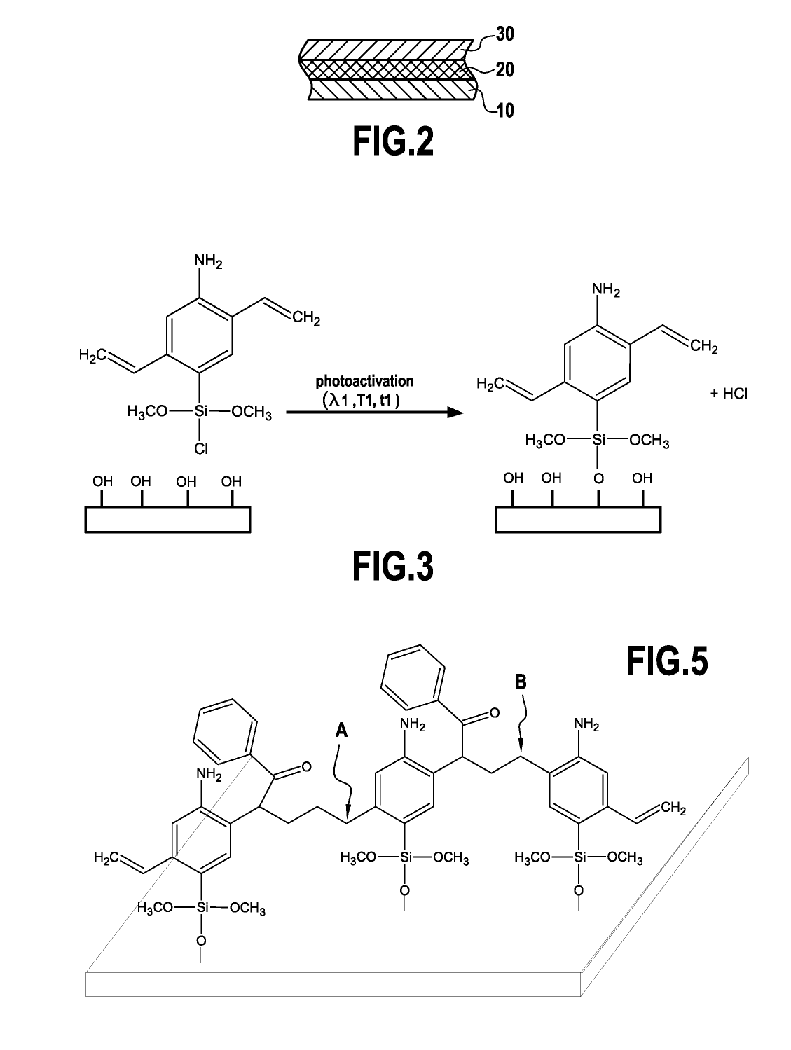

Thus, in a resultant semiconductor device structure, an underlying layer, such as a dielectric layer 10 (which may be porous, as discussed above), has a coupling layer 20 formed thereon. The coupling layer 30 promotes the formation of a metal layer 30 (such as a sidewall barrier layer) thereon. See FIG. 2.

The coupling material of the present invention can be applied on the surface of a porous dielectric material in accordance with known method for applying polymeric compositions including, generally and without limitation, gas phase, liquid phase, or spray chamber application. The physical equipment necessary for each type of application is considered well-known in the art.

With respect to liquid phase deposition of the coupling material, the present invention most generally contemplates the use of an aqueous solution containing the coupling material to deposit a coupling layer over a dielectric layer. The coupling material is typically diluted in water, possibly with an organic solvent (such as, for example, alcohol) added to further increase the solubility of the polymer. Also, some of the noted examples of functional groups suitable for the present invention can be hydrolyzed.

Liquid phase application can be performed, for example, at temperatures between about 25° C. and 80° C. with process times between about 30 s to 10 min.

Preferably, the reaction speed between the coupling material and silanols formed on the surface of the porous dielectric layer is sufficiently fast such that that reaction takes places before any appreciable uptake of moisture from the aqueous solvent occurs. In other words, the reaction desirably should be fast enough to sterically shield the porous dielectric layer before the dielectric layer starts adsorbing water from the solvent.

If the surface in question needs to be cleaned of residues or deposits before the coupling material can be deposited, the coupling material could be combined with an aqueous cleaning composition appropriate for removing the polymeric residues. As mentioned above, the reaction speed should be sufficiently fast so that the coupling material reacts with hydroxyl groups on the surface of the porous dielectric material essentially as soon as the unwanted residues are removed by the cleaning composition. Water adsorption can therefore be blocked. A cleaning process step and a coupling layer deposition step can therefore be carried out at the same time, which would correspondingly simplify the fabrication process.

If the coupling material is a water-soluble organosilane, it can be mixed with the cleaning fluid(s) ahead of application thereof to the wafer. It can also be mixed with the cleaning fluid(s) at, or in the immediate vicinity of, the cleaning tool (i.e., just before application to the wafer).

According to one example of combining a cleaning solution and the coupling material of the present invention, application of the combined solution is implemented according to the following parameters:
the applied cleaning mixture is a soluble organosilane according to the description herein, mixed with an organic acid, a highly diluted aqueous HF, or a salt thereof, and optionally includes a chelating agent and/or surfactant
process temperature=25-80° C., and
process time=30 s to 10 min

After the residual polymers and/or metallic residues are removed as desired, the porous dielectric material is sealed by the passivating coupling layer as described.

Complexing or chelating agents may also be provided in order to remove metallic species, if needed. These reagents should be added into the solution so as to be able to be processed in a common series of steps. Common complexing agents include ethylenediaminetetraacetic acid (EDTA) and its derivatives and organic acids.

Similarly, a wide variety of conventional surfactants can be included in the solution. For example, it may be advantageous to use block co-polymers built from blocks of poly(ethyleneoxide) and poly(propyleneoxide) as a surfactant. These two groups efficiently adsorb on both hydrophobic and hydrophilic surfaces, and the length and ratio of each group present in the block co-polymer can easily be tailored to the application.

Instead of liquid deposition of the passivating coupling material using an aqueous solution, it can be applied in gas phase using conventional gas dispersion means (nozzles, vents, etc.) to disperse a carrier gas (like nitrogen or argon) combined with the material. Gas phase application can be performed between about 0° C. and about 300° C.

In order to avoid the difficulties of using an aqueous solution application, a spray application in a predetermined environment (particularly in an inert environment) could be considered. The environment may for example be argon, nitrogen, or carbon dioxide, with, for example, a humidity of less than about 1%. The inert atmosphere may be at ambient pressure. In this case, one or more aerosol nozzles may be provided in a substantially sealed chamber at the processing stations. The inert atmosphere can be at reduced or increased pressure versus ambient pressure as well.

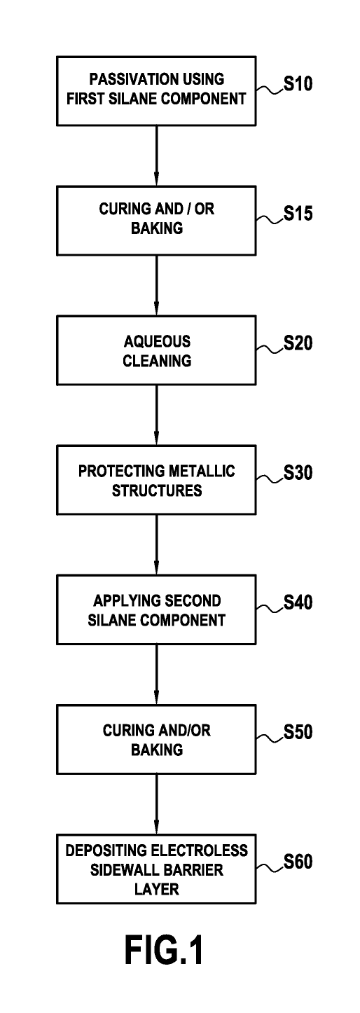

In view of the foregoing, an example of a process sequence according to the present invention includes (see, generally, FIG. 1):

passivating the dielectric layer with a first silane component (for example, by controlled atmosphere spraying or by vapor phase deposition) (step S10), this step may include light assist or photoactivation (wavelengths ranging from UV to thermal infrared light);

curing (particularly, but not exclusively, UV curing) and/or baking in a controlled atmosphere, especially to induce photopolymerization (i.e., crosslinking) (step S15);

aqueous cleaning of vias, so as to simultaneously hydrolyze one or more functional groups of the deposited first silane component (such as the first polymeric components described above) (using, for example, liquid phase application, controlled atmosphere spray, or vapor phase deposition); may include drying and/or light assists (step S20) (wavelengths ranging from UV to thermal infrared light);

optionally protecting a metallic layer (such as a copper cap layer) in the device structure to prevent or at least weaken bonding between the passivating coupling material and the metallic layer, as described above (in a controlled atmosphere, or in vapor phase) (step S30);

applying a second silane component (such as described above) (for example, in liquid phase, spray (optionally using an organic solvent), or in vapor phase; may optionally include drying assist); may include drying and/or light assists (step S40) (wavelengths ranging from UV to thermal infrared light);

curing (particularly, but not exclusively, UV curing) and/or baking in a controlled atmosphere (step S50); and

depositing an electroless sidewall barrier layer in liquid phase (for example, using immersion or spray); optionally with drying and/or light assists (step S60) (wavelengths ranging from UV to thermal infrared light);

Once the porous dielectric material is appropriately passivated with the passivating coupling material of the present invention (whether in a single step or in multiple steps), metallization can be performed thereafter in liquid phase starting with an electroless deposition (as known, for example, from Shacham-Diamand, Electroch. Acta, vol. 44 (1999), 3639). After deposition of a barrier/seed layer in this fashion, a copper film can be deposited thereon by conventional electrodeposition, as is known in the field of semiconductor manufacture. Liquid application of the barrier metal layer on the passivating coupling layer permits metal deposition on the passivating coupling layer without having to “switch” process lines to gas phase metal deposition equipment.

The liquid phase barrier metal deposition can be performed in accordance with the foregoing description, for example, by seeding the nucleation sites presented by the passivating coupling material as described and claimed herein using liquid metal precursors or solutions of metal salts (such as cobalt or nickel), in a manner well known in the field of metal deposition.

The above-described presence of multiple Si atoms in the backbone, plus the optional presence of a bridging group B, increases the thermal stability of the passivating coupling material such that it can tolerate the temperatures associated with subsequent high-temperature manufacturing steps, such as gas phase deposition of a subsequent metal layer. In contrast, thermal decomposition of the shielding groups, if any, can be acceptable because their steric shielding function is no longer needed at that point.

In addition, the ligand L has an electron donor functionality and provides nucleation sites for the subsequently deposited metal. The fact that Z₁ and/or Z₂ can additionally be corresponding ligands further enhances the formation of a metal layer by presenting additional nucleation sites.

In a particular example of the present invention, the passivating coupling composition (whether deposited as a complete molecule or as multiple organic components, as discussed above) is chemically attached to the surface of the dielectric layer by reacting with hydroxyl groups thereon (irrespective of a particular means of application). In FIG. 3, an organosilane is reacted with the surface of the dielectric layer. The reaction can be photoactivated or otherwise promoted by a first exposure to a predetermined light having a wavelength λ₁ for a time t₁ and at a temperature T₁. As with all of the photoactivation steps referred to herein, the wavelength, time, and temperature may fall generally in the range of: about 190 nm to about 10 μm; for about 1 to 1000 seconds; at a temperature between about 0° C. and 400° C. In a particular example, the wavelength may be between 190 nm and 500 nm, the exposure time may be between 1 and 60 seconds, and the temperature may be between 10° C. and 100° C.

An Si—O—Si bond is therefore formed between the organosilane and the dielectric layer surface.

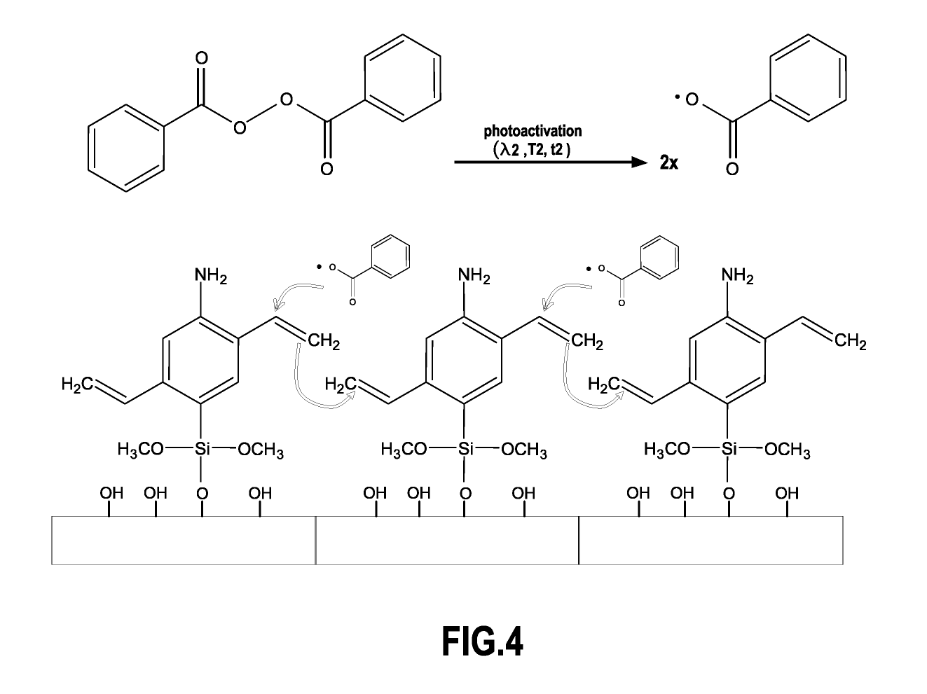

Next, reference is made to FIG. 4. FIG. 4 generally illustrates a plurality of organosilanes corresponding to the passivating coupling composition bound to the surface of the dielectric layer. In general, respective adjacent functional groups (i.e., steric shielding groups) of adjacent organosilanes are cross-linked so as to provide a bidimensional (i.e., in the transverse sense) polymerization effect.

In this regard, a photoactivated polymerization initiator (such as benzoyl peroxide) can be used. For example, FIG. 4 illustrates how a molecule of benzoyl peroxide under exposure to a second light having a wavelength λ₂ for a time t₂ at a temperature T₂ breaks down into two radicals which are each polymerization initiators. As before, the wavelength, time, and temperature may fall generally in the range of: about 190 nm to about 10 μm; for about 1 to 1000 seconds; at a temperature between about 0° C. and 400° C. In a particular example, the wavelength may be between 190 nm and 500 nm, the exposure time may be between 1 and 60 seconds, and the temperature may be between 10° C. and 100° C.

Each polymerization initiator acts to initiate a radical-type polymerization chain reaction between adjacent CH₂ groups of respective first organosilanes.

Therefore, as seen in perspective in FIG. 5, respective molecules of the passivating coupling layer are laterally cross-linked so as to provide an enhanced pore-sealing functionality. In addition to the cross-linking between the illustrated molecules, references A and B indicate some locations of additional cross-linking or polymerization termination. Molecules linked in that fashion are forming a layer structure corresponding to layer 20 in FIG. 2. At the same time, each molecule presents a ligand group (such as NH₂, in the illustrated example), which acts a metal nucleation site for electroless metal deposition (such as electroless deposition of a metal sidewall barrier layer). Once a metal layer is deposited thereon, a layer structure as illustrated in FIG. 2 is obtained. Although not specifically illustrated in the drawings, photoactivation may also be used to enhance the metal deposition. As before, the wavelength, time, and temperature may fall generally in the range of: about 190 nm to about 10 μm; for about 1 to 1000 seconds; at a temperature between about 0° C. and 400° C. In a particular example, the wavelength may be between 190 nm and 500 nm, the exposure time may be between 1 and 60 seconds, and the temperature may be between 10° C. and 100° C.

It was explained above that the ligands L provided in the passivating coupling material are meant to provide metal nucleation sites in order to promote or facilitate metal layer formation. However, the ligands L may in certain situations tend to be reactive with other metallic structures in a semiconductor device, such as copper metal exposed in etched vias, or metallic barrier layers in the semiconductor device (such as, for example, a cobalt alloy-based self-aligned barrier layer, as is known in the art).

As described hereinabove, the passivating coupling material has one or more functional groups X at an “end” thereof that are able to react with a surface hydroxyl site present on a dielectric material. The other “end” of the polymer has ligand(s) for providing metal nucleation sites to promote metal layer formation. However, a problem could arise if, for example, the ligands L instead reacted with, for example, a copper metal structure in an exposed via (with the functional groups X either reacting with surface hydroxyls as intended, or perhaps remaining unattached such that the polymer is in a sense inverted from its intended state). As a result, the passivating coupling material would present a reduced ability to promote metal layer deposition because of the reduction in available ligands acting as nucleation sites. Accordingly, it may be desirable to formulate the passivating coupling material to reduce or avoid such interaction with other metallic structures forming part of the semiconductor device.

Alternatively, some additional processing steps could be implemented in order to render the metal structures relatively insensitive to the passivating coupling material. For example, the surface of a copper metal structure could be treated (i.e., protectively covered with) with a chemically appropriate organic amine. This modification of the copper metal surface can give rise to chemical bonds with the passivating coupling material which are weaker than those between the passivating coupling material and the dielectric material thereunder. When the passivating coupling material has been thereafter deposited as desired, a subsequent degassing step (using, for example, a thermal treatment) can be applied to remove any passivating coupling material from the copper metal areas, this being facilitated by the above-mentioned weak bonds created by the pretreatment of the copper metal surface.

In an alternative process (also applicable to porous dielectrics), aqueous via cleaning could be replaced by an initial step of via cleaning using supercritical CO₂. This would be followed by a step of depositing a first organosilane as described above, and a step of hydrating the structure to obtain distal hydroxyl sites on the first organosilane molecules. The thusly modified first organosilane can then react with one of the second organosilanes described above. Electroless barrier deposition and electroless or electrodeposition of copper would then follow.

In yet another alternative process (applicable to a conventional PTEOS SiO₂ dielectric), a conventional aqueous via cleaning is first performed. Then, the first organosilane as described above is applied using suitable methods (such as liquid phase deposition, spray, or vapor phase deposition). The structure is then hydrated in an aqueous media to obtain hydroxyls at the ends of the first organosilanes formed on the dielectric layer structure. One of the second organosilanes is then deposited as described above, followed by electroless barrier layer deposition and electroless or electrodeposition of copper.

As mentioned above, the present invention relates in part to an integrated system for processing semiconductor substrates in the course of manufacturing semiconductor devices. The system includes a plurality of processing stations, along with a transport mechanism for moving a semiconductor substrate between the processing stations. The processing stations use liquid phase deposition instead of gas or vapor phase deposition to the extent possible in order to permit faster, simpler, and less expensive processing.

The plurality of processing stations includes at least a metal barrier layer deposition station for depositing a liquid phase metallic barrier layer. The system may also include a coupling layer deposition station for depositing a coupling layer having a chemical composition that functions to promote and otherwise facilitate the subsequent formation of the metallic barrier layer. An example of such a coupling layer composition is described in Patent Application No. PCT/EP2005/010688.

Other processing stations for providing conventional processing steps can be included in the system in any appropriate or otherwise desired combination. Examples of other processing stations that could be provided in the integrated system of the present invention include a substrate cleaning station, an electroplating station, a seed layer deposition station, a polishing station, a photoactivation station (using electromagnetic energy ranging in wavelength from infrared to ultraviolet) having a controlled atmosphere, and a passivation layer deposition station. These stations use conventional approaches in order to provide their respective functionalities.

A particular aspect of the present invention supplements one or more stages of processing (as explained herein) with a light treatment (particularly, a UV light treatment) to promote, for example, polymerization (particularly, cross-polymerization) of the passivating coupling material.

A transport system is provided in order to transport semiconductor substrates from one station to another. According to one aspect of the present invention, the transport system is automatically controlled in a known manner, such as by appropriate control software running on a computer.

The transport system may be of any conventional type known in the art. These include systems of trays and the like for holding a respective semiconductor substrate thereon, cassettes for holding more than one semiconductor substrate, or automatically controlled grabbers, pincers, or the like. Each substrate holding unit for retaining a substrate (that is, each tray, cassette, grabber, etc.) may be moved throughout the processing system from station to station in a known manner, such as by attaching each unit to circulating cables, chains, conveyors or the like. The movement of each substrate holding unit is also preferably automatically controlled.

Transport systems structured along linear paths of travel may be particularly suitable for serial processing of a semiconductor substrate in which a sequence of processing stations are used in a unidirectional order, without backtracking.

In contrast, it may be useful to provide a centrally located transport system with respect to a cluster of processing stations, such as a robotic arm provided with, for example, a known gripper type end located so as to be surrounded by the plurality of processing stations. This arrangement is useful if one or more processing stations (such as a thermal treatment station) are used more than once during fabrication. In addition, this arrangement can present a desirably reduced footprint. Known examples of this general physical arrangement are illustrated in U.S. Pat. No. 6,352,467 and U.S. Pat. No. 6,294,059.

Contamination of semiconductor substrates during manufacture is a well-recognized problem in the art of semiconductor manufacturing art. Accordingly, it should be understood that conventional measures to avoid contamination are preferably a part of the system as contemplated, such as defining a closed environment in which substrates are transmitted from one station to another. Other known environmental controls may be applied as needed or desired, for example and without limitation, providing a slight overpressure within the integrated system, using technically appropriate construction materials to avoid chemical reactions with structures on the substrates, etc.

Cassettes holding a plurality of semiconductor substrates can be used to increase the throughput of processing, instead of moving substrates through the integrated system one at a time. An example of such a cassette is described, for example, in U.S. Pat. No. 6,352,467.

Although not described in particular detail here, one or more additional processing stations can be provided according to the nature of the semiconductor device being fabricated, including, without limitation, stations for electroplating (including electroplating a copper film on the barrier layer), polishing (for example, chemical mechanical polishing or electro-polishing), or seed layer deposition. As mentioned above, a separate semiconductor substrate cleaning station could be provided or that functionality could be combined with that of coupling layer deposition station.

Although the present invention has been described above with reference to certain particular preferred embodiments, it is to be understood that the invention is not limited by reference to the specific details of those preferred embodiments. More specifically, the person skilled in the art will readily appreciate that modifications and developments can be made in the preferred embodiments without departing from the scope of the invention as defined in the accompanying claims.

1. An integrated semiconductor substrate processing system, comprising:
a plurality of semiconductor substrate processing stations including at least a barrier layer deposition station constructed and arranged to deposit a barrier layer on the semiconductor substrate; and
a semiconductor substrate transport system for transferring a semiconductor substrate between the plurality of semiconductor substrate processing stations, wherein the barrier layer deposition station is constructed and arranged to deposit a metallic barrier layer in liquid phase, and in that it further comprises a coupling layer deposition station constructed and arranged to deposit a bidimensionally polymerized coupling layer on a dielectric layer previously deposited on the semiconductor substrate prior to depositing the barrier layer thereon, the coupling layer functioning to promote the formation of the barrier layer thereon.

2. A system according to claim 1, wherein the coupling layer deposition station is constructed and arranged to deposit an organosilane coupling layer having a molecular composition according to the general formula: 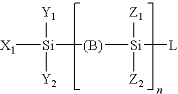
in which:
n is an integer equal to or greater than 1,
each Si is a silicon atom;
X₁ is a functional group able to react with a surface hydroxyl site of the dielectric material,
Y₁ is either:
X₂, which is a further functional group able to react with a surface hydroxyl site of the dielectric material,
H, which is a hydrogen atom, or
R₁, which is an organic group;
Y₂ is either:
X₃, which is a further functional group able to react with a surface hydroxyl site of the dielectric material,
H, which is a hydrogen atom, or
R₂, which is an organic group,
B, the presence of which is optional, is a bridging group,
Z₁ is either:
R₃, which is an organic group,
H, which is a hydrogen atom, or
L₁, which is a ligand having an electron donor functionality and is able to act as a metal nucleation site for promoting the formation of the barrier layer,
Z₂ is either:
R₄, which is an organic group,
H, which is a hydrogen atom, or
L₂, which is a ligand having an electron donor functionality and which is able to act as a metal nucleation site for promoting the formation of the barrier layer, and
L is a ligand able to act as a metal nucleation site for promoting the formation of the barrier layer,
wherein at least some of the organic groups R are able to react with a respective organic group R of another one of the organosilane molecules of the organosilane coupling layer so as to be cross-linked.

3. A system according to claim 2, wherein at least one of Z₁ and Z₂ is, respectively, R₃ and R₄.

4. A system according to claims 2, wherein n is an integer between 1 and 30, inclusive, and is more particularly an integer having a value of 1, 2, 3, 4, 5, 6, 7, 8, 9, 10, 11, 12, 13, 14, 15, 16, 17, or 18.

5. A system according to claim 2, wherein:
X₁, and X₂ and/or X₃ if present, are selected from the group consisting of: -chloride, -bromide, iodide, acryloxy-, alkoxy-, acetamido, acetyl-, allyl-, amino-, cyano-, epoxy-, imidazolyl, mercapto-, methanosulfonato-, sulfonato-, trifluoroacetamido, and urea-containing groups, and
L, and L₁ and/or L₂ if present, is selected from the group consisting of vinyl, allyl, 2-butynyl, cyano, cyclooctadienyl, cyclopentadienyl, phosphinyl, alkylphosphinyl, sulfonato, amine groups, carboxylic acids, carboxylates, and thiols.

6. A system according to claim 1, wherein B, if present, is a silylene or a carbene group.

7. A system according to claim 6, wherein B is selected from the group consisting of m-phenylene, p-phenylene, and p,p′-diphenyl ether.

8. A system according to claim 1, wherein R₁, R₂, R₃, and/or R₄, if present, are selected from the group consisting of methyl, ethyl, propyl, butyl, phenyl, pentafluorophenyl, 1,1,2-trimethylpropyl (thexyl), and allyl.

9. A system according to claim 2, comprising a dielectric layer deposition station constructed and arranged to deposit a dielectric layer, wherein the coupling layer deposition station is constructed and arranged to deposit the coupling layer on the deposited dielectric layer.

10. (canceled)

11. (canceled)

12. (canceled)

13. (canceled)

14. (canceled)

15. (canceled)

16. (canceled)

17. (canceled)

18. (canceled)

19. (canceled)

20. A system according to claim 1, wherein the coupling layer deposition station is constructed and arranged to deposit a first organosilane on the previously deposited dielectric layer, the first organosilane having a functional group able to react with a surface hydroxyl site of the dielectric layer and having the general formula: 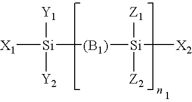
in which:
n₁ is an integer greater than or equal to 1,
each Si is a silicon atom;
X₁ is a functional group able to react with a surface hydroxyl site of the dielectric material,
Y₁ is either:
X₃, which is a further functional group able to react with a surface hydroxyl site of the dielectric material,
H, which is a hydrogen atom, or
R₁, which is an organic group;
Y₂ is either:
X₄, which is a further functional group able to react with a surface hydroxyl site of the dielectric material,
H, which is a hydrogen atom, or
R₂, which is an organic group,
B₁, the presence of which is optional, is a bridging group,
Z₁ is either:
R₃, which is an organic group,
H, which is a hydrogen atom, or
X₅, which is a hydrolizable functional group,
Z₂ is either:
R₄, which is an organic group,
H, which is a hydrogen atom, or
X₆, which is a hydrolizable functional group; and
X₂ is a hydrolizable functional group.

21. A system according to claim 20, wherein the coupling layer deposition station is further constructed and arranged to deposit a second organosilane having a functional group able to react with a hydrolyzed functional group of the first organosilane and a ligand for providing a metal nucleation site, the second organosilane having the general formula: 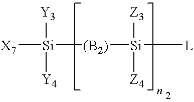
in which:
n₂ is an integer equal to or greater than or equal to 0,
each Si is a silicon atom;
X₇ is a functional group able to react with a hydrolyzed functional group of the first organosilane molecule,
Y₃ is either:
X₈, which is a further functional group able to react with a hydrolyzed functional group of the first organosilane molecule,
H, which is a hydrogen atom, or
R₅, which is an organic group;
Y₄ is either:
X₉, which is a further functional group able to react with a hydrolyzed functional group of the first organosilane molecule,
H, which is a hydrogen atom, or
R₆, which is an organic group,
B₂, the presence of which is optional, is a bridging group,
Z₃ is either:
R₇, which is an organic group,
H, which is a hydrogen atom, or
L₁, which is a ligand having an electron donor functionality and which is able to act as a metal nucleation site,
Z₄ is either:
R₈, which is an organic group,
H, which is a hydrogen atom, or
L₂, which is a ligand having an electron donor functionality and which is able to act as a metal nucleation site, and
L is a ligand having an electron donor functionality and is able to act as a metal nucleation site,
wherein the first and second organosilanes together constitute a composition providing metal nucleation sites that promote electroless metal deposition.

22. (canceled)

23. (canceled)

24. (canceled)

25. (canceled)

26. A method of forming a coupling layer on a dielectric layer having hydroxyl groups on a surface thereof, comprising:
depositing a first organosilane on the dielectric layer, the first organosilane having the general formula: 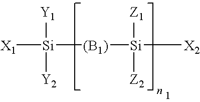
in which:
n₁ is an integer greater than or equal to 1,
each Si is a silicon atom;
X₁ is a functional group able to react with a surface hydroxyl site of the dielectric material,
Y₁ is either:
X₃, which is a further functional group able to react with a surface hydroxyl site of the dielectric material,
H, which is a hydrogen atom, or
R₁, which is an organic group;
Y₂ is either:
X₄, which is a further functional group able to react with a surface hydroxyl site of the dielectric material,
H, which is a hydrogen atom, or
R₂, which is an organic group,
B₁, the presence of which is optional, is a bridging group,
Z₁ is either:
R₃, which is an organic group,
H, which is a hydrogen atom, or
X₅, which is a hydrolizable functional group,
Z₂ is either:
R₄, which is an organic group,
H, which is a hydrogen atom, or
X₆, which is a hydrolizable functional group; and
X₂ is a hydrolizable functional group,
such that at least some of the functional groups of the first organosilane react with hydroxyl groups formed on the dielectric layer, hydrolyzing at least the hydrolizable functional group X₂ of the first organosilane; and
depositing a second organosilane having a functional group able to react with the hydrolyzed functional group of the first organosilane, and a ligand for providing a metal nucleation site, the second organosilane having the general formula: 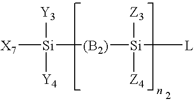
in which:
n₂ is an integer equal to or greater than or equal to 0,
each Si is a silicon atom;
X₇ is a functional group able to react with a hydrolyzed functional group of the first organosilane molecule,
Y₃ is either:
X₈, which is a further functional group able to react with a hydrolyzed functional group of the first organosilane molecule,
H, which is a hydrogen atom, or
R₅, which is an organic group;
Y₄ is either:
X₉, which is a further functional group able to react with a hydrolyzed functional group of the first organosilane molecule,
H, which is a hydrogen atom, or
R₆, which is an organic group,
B₂, the presence of which is optional, is a bridging group,
Z₃ is either:
R₇, which is an organic group,
H, which is a hydrogen atom, or
L₁, which is a ligand having an electron donor functionality and which is able to act as a metal nucleation site,
Z₄ is either:
R₈, which is an organic group,
H, which is a hydrogen atom, or
L₂, which is a ligand having an electron donor functionality and which is able to act as a metal nucleation site, and
L is a ligand having an electron donor functionality and is able to act as a metal nucleation site,
reacting at least some of the functional groups X₇ and, if present, X₈ and X₉, of the second organosilane with a respective hydrolyzed functional group of the first organosilane, and
cross-linking at least some respective combinations of first and second organosilanes,
wherein at least one of:
the reaction between the first organosilane and hydroxyl groups on the dielectric layer, and
the cross-linking of respective combinations of first and second organosilanes
is carried out with a photo-activation step.

27. A method according to claim 26, wherein the photo-activation step is dependent on one or more of light wavelength, time of exposure, and temperature.

28. A method according to claim 27, where the photo-activation step uses light at a wavelength between 190 nm to 10 μm.

29. A method according to claim 28, wherein the photo-activation step uses light at wavelength between 190 nm to 500 nm.

30. A method according to claim 27, wherein the time of exposure is between 1 and 1000 seconds.

31. A method according to claim 27, wherein the time of exposure is between 1 and 60 seconds.

32. A method according to claim 27, wherein the temperature at which the photo-activation step is performed is between 0° C. and 400° C.

33. A method according to claim 27, wherein the temperature at which the photo-activation step is performed is between 10° C. and 100° C.

34. A semiconductor device comprising:
a dielectric layer,
a coupling layer formed on the dielectric layer; and
a metal layer formed on the coupling layer,
wherein molecules of the coupling layer are bidimensionally polymerized and have a general molecular formula of: 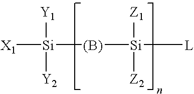
in which:
n is an integer equal to or greater than 1 (i.e., 1, 2, 3, 4, 5, 6, 7 . . . ),
each Si is a silicon atom;
X₁ is a functional group able to react with a surface hydroxyl site of the porous dielectric material.
Y₁ is either:
X₂, which is a further functional group able to react with a surface hydroxyl site of the porous dielectric material,
H, which is a hydrogen atom, or
R₁, which is an organic group;
Y₂ is either:
X₃, which is a further functional group able to react with a surface hydroxyl site of the porous dielectric material,
H, which is a hydrogen atom, or
R₂, which is an organic group
B, the presence of which is optional, is a bridging group,
Z₁ is either:
R₃, which is an organic group,
H, which is a hydrogen atom, or
L₁, which is a further ligand having an electron donor functionality and is able to act as a metal nucleation site,
Z₂ is either:
R₄, which is an organic group,
H, which is a hydrogen atom, or
L₂, which is a further ligand having an electron donor functionality and is able to act as a metal nucleation site, and
L is a ligand having an electron donor functionality and is able to act as a metal nucleation site.
